(19) United States
(12) Patent Application Publication
(10) Pub. No.: US 2013/0238916 A1
(43) Pub. Date: Sep. 12, 2013

(54) METHOD FOR IMPLEMENTING ISOLATION GATES DURING LOW-POWER MODES

(71) Applicant: CONEXANT SYSTEMS, INC., Newport Beach, CA (US)

(72) Inventors: Nathan J. Dohm, Natick, MA (US); Steven J. Morris, West Newton, MA (US); Michael J. Schaffstein, Needham, MA (US)

(73) Assignee: CONEXANT SYSTEMS, INC., Newport Beach, CA (US)

(21) Appl. No.: 13/790,967

(22) Filed: Mar. 8, 2013

Related U.S. Application Data
(60) Provisional application No. 61/608,401, filed on Mar. 8, 2012.

(51) Int. Cl. G06F 1/32; H03K 3/012

(52) U.S. Cl. CPC G06F 1/32; H03K 3/012
USPC 713/320; 327/142

(57) ABSTRACT

A power-saving block may be isolated from a remainder of a digital circuit. To save power, the power-saving block may be powered down when not in use. To prevent the power-down process from creating metastable states in the remainder of the digital circuit, appropriate isolation gates may separate outputs of the power-saving block from the remainder of the digital circuit. Signals may be sent to the power-saving block to ensure that the output signals from the power-saving block are always the same value during the power-down process. The isolation gates may be chosen based on the value expected on the output signals during the power-down process. Assertions may be used to confirm that the correct isolation gates were selected.

### RELATED APPLICATIONS

This present application claims the benefit under 35 U.S.C. §119(e) of U.S. Provisional Patent Application No. 61/608,401 filed Mar. 8, 2012, titled “METHOD FOR IMPLEMENTING ISOLATION GATES DURING LOW-POWER MODES,” which application is incorporated herein by reference in its entirety.

### TECHNICAL FIELD

This disclosure relates to methods of isolating a digital circuit from a circuit block being powered down. More specifically, the disclosure relates to a method of ensuring that output signals from the circuit block do not vary during power down.

### BRIEF DESCRIPTION OF THE DRAWINGS

Non-limiting and non-exhaustive embodiments of the disclosure are described, including various embodiments of the disclosure with reference to the figures, in which:

FIG. 1 is a block diagram of a digital circuit including a power-saving block.

FIG. 2 is a block diagram of a digital circuit with isolation gates coupled to the output signals from the power-saving block.

FIG. 3 is a flow diagram of a method for powering down the power-saving block while ensuring the output signals will remain at a definite level.

FIG. 4 is a flow diagram of a method for powering up a power-saving block while ensuring the output signals will remain at a definite level.

FIG. 5 is a block diagram of a system for selecting appropriate isolation gates.

FIG. 6 is a flow diagram of a method that may be used by the isolation gate selector to determine the appropriate isolation gates for a noncompliant circuit block.

### DETAILED DESCRIPTION OF PREFERRED EMBODIMENTS

Electrical circuits may consume large amounts of energy during operation. The energy consumption has increased as advances in technology have decreased the size of individual circuit components. The increased energy consumption increases the temperature of the circuit, which can damage the circuit, reduce battery performance for mobile devices, and lead to increased expense in purchasing energy. Therefore, it is desirable to use methods to reduce the energy consumption of electrical circuits.

Many modern digital or logical circuits include numerous field effect transistors. In a field effect transistor, the voltage at a gate terminal controls the flow of current across a channel between source and drain terminals. A dielectric separates the gate terminal from the drain and source, but leakage current may still flow between the gate terminal and the channel. Higher performance circuits may use thinner dielectrics, which results in more leakage current. For electrical circuits comprised mostly of field effect transistors, the majority of energy consumption comes from leakage current.

One method of reducing energy consumption is to power down a section of a digital circuit when that section is not needed. The digital circuit may comprise two or more power supply rails with the transistors and other circuit components connected between those rails. A section may be powered down by reducing the voltage between the rails to zero. Powering down is often accomplished by reducing the voltage on a high voltage power supply until it equals the voltage on a grounded or low voltage power supply rail, but the voltage of the low voltage power supply rail could also be raised to until it equals the voltage on a high voltage power supply. The section of the circuit that is powered down may be referred to as powered down, unpowered, or in standby. The unpowered section of the circuit consumes very little energy, while the overhead logic needed to control the powering down and powering up the unpowered section consumes minimal additional energy. As a result, power savings of 80 to 90% or more can be achieved even when the extra power consumption of the overhead logic is considered.

The embodiments of the disclosure will be best understood by reference to the drawings, wherein like parts are designated by like numerals throughout. The described features, structures, or characteristics may be combined in any suitable manner in one or more embodiments. Those skilled in the art will recognize that the invention can be practiced without one or more of the specific details, or with other methods, components, materials, etc. In other instances, well-known structures, materials, or operations are not shown in detail to avoid obscuring aspects of the invention.

Furthermore, the described features, operations, or characteristics may be combined in any suitable manner in one or more embodiments. It will also be readily understood that the order of the steps or actions of the methods described in connection with the embodiments disclosed may be changed as would be apparent to those skilled in the art. Thus, any order in the drawing or Detailed Description is for illustrative purposes only and is not meant to imply a required order, unless specified to require an order.

Embodiments may include various steps, which may be embodied in machine-executable instructions to be executed by a computer system. A computer system comprises one or more general-purpose or special-purpose computers (or other electronic device). Alternatively, the computer system may comprise hardware components that include specific logic for performing the steps or comprise a combination of hardware, software, and/or firmware.

Embodiments may also be provided as a computer program product including a machine-readable storage medium having stored thereon instructions that may be used to program a computer (or other electronic device) to perform processes described herein. The machine-readable storage medium may include, but is not limited to, hard drives, floppy diskettes, optical disks, CD-ROMs, DVD-ROMs, ROMs, RAMs, EPROMs, EEPROMs, magnetic or optical cards, solid-state memory devices, or other types of media/machine-readable medium suitable for storing electronic instructions.

The computers in a computer system comprising more than one computer may be connected via a network. Suitable networks for configuration and/or use as described herein include one or more local area networks, wide area networks, metropolitan area networks, and/or “Internet” or IP networks, such as the World Wide Web, a private Internet, a secure Internet, a value-added network, a virtual private network, an extranet, an intranet, or even standalone machines which communicate with other machines by physical transport of media (a so-called “sneakernet”). In particular, a suitable network may be formed from parts or entireties of two or more other networks, including networks using disparate hardware and network communication technologies.

One suitable network includes a server and several clients; other suitable networks may contain other combinations of servers, clients, and/or peer-to-peer nodes, and a given computer system may function both as a client and as a server. Each network includes at least two computer systems, such as the server and/or clients. A computer system may comprise a workstation, laptop computer, disconnectable mobile computer, server, mainframe, cluster, so-called “network computer” or “thin client,” tablet, smart phone, personal digital assistant or other hand-held computing device, “smart” consumer electronics device or appliance, or a combination thereof.

The network may include communications or networking software, such as the software available from Novell, Microsoft, Artisoft, and other vendors, and may operate using TCP/IP, SPX, IPX, and other protocols over twisted pair, coaxial, or optical fiber cables, telephone lines, satellites, microwave relays, modulated AC power lines, physical media transfer, and/or other data transmission “wires” known to those of skill in the art. The network may encompass smaller networks and/or be connectable to other networks through a gateway or similar mechanism.

Each computer system includes at least a processor and a memory; computer systems may also include various input devices and/or output devices. The processor may include a general purpose device, such as an Intel®, AMD®, or other “off-the-shelf” microprocessor. The processor may include a special purpose processing device, such as an ASIC, SoC, SiP, FPGA, PAL, PLA, FPLA, PLD, or other customized or programmable device. The memory may include static RAM, dynamic RAM, flash memory, ROM, CD-ROM, disk, tape, magnetic, optical, or other computer storage medium. The input device(s) may include a keyboard, mouse, touch screen, light pen, tablet, microphone, sensor, or other hardware with accompanying firmware and/or software. The output device(s) may include a monitor or other display, printer, speech or text synthesizer, switch, signal line, or other hardware with accompanying firmware and/or software.

The computer systems may be capable of using a floppy drive, tape drive, optical drive, magneto-optical drive, or other means to read a storage medium. A suitable storage medium includes a magnetic, optical, or other computer-readable storage device having a specific physical configuration. Suitable storage devices include floppy disks, hard disks, tape, CD-ROMs, DVDs, PROMs, random access memory, flash memory, and other computer system storage devices. The physical configuration represents data and instructions which cause the computer system to operate in a specific and predefined manner as described herein.

Suitable software to assist in implementing the invention is readily provided by those of skill in the pertinent art(s) using the teachings presented here and programming languages and tools, such as Java, Pascal, C++, C, database languages, APIs, SDKs, assembly, firmware, microcode, and/or other languages and tools. Suitable signal formats may be embodied in analog or digital form, with or without error detection and/or correction bits, packet headers, network addresses in a specific format, and/or other supporting data readily provided by those of skill in the pertinent art(s).

Several aspects of the embodiments described will be illustrated as software modules or components. As used herein, a software module or component may include any type of computer instruction or computer executable code located within a memory device. A software module may, for instance, comprise one or more physical or logical blocks of computer instructions, which may be organized as a routine, program, object, component, data structure, etc., that performs one or more tasks or implements particular abstract data types.

In certain embodiments, a particular software module may comprise disparate instructions stored in different locations of a memory device, different memory devices, or different computers, which together implement the described functionality of the module. Indeed, a module may comprise a single instruction or many instructions, and may be distributed over several different code segments, among different programs, and across several memory devices. Some embodiments may be practiced in a distributed computing environment where tasks are performed by a remote processing device linked through a communications network. In a distributed computing environment, software modules may be located in local and/or remote memory storage devices. In addition, data being tied or rendered together in a database record may be resident in the same memory device, or across several memory devices, and may be linked together in fields of a record in a database across a network.

Much of the infrastructure that can be used according to the present invention is already available, such as: general purpose computers, computer programming tools and techniques, computer networks and networking technologies, digital storage media, and the like.

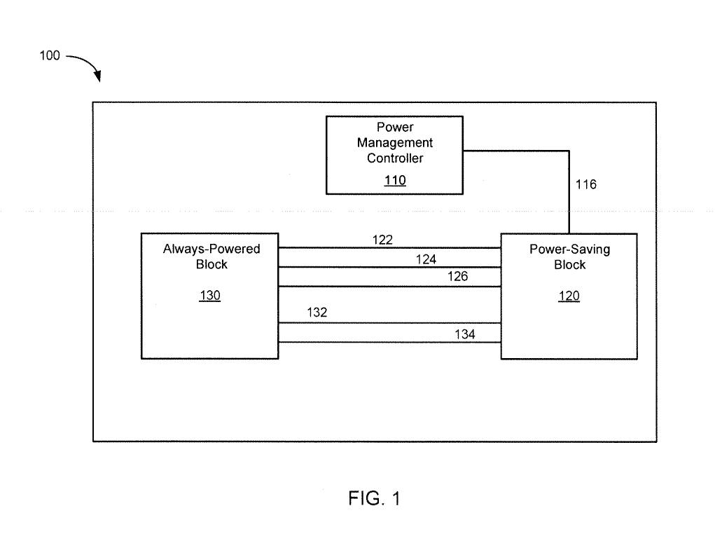

FIG. 1 is a block diagram of a digital circuit 100 comprising multiple functional blocks including a power-saving block. Each functional block may be a section of the digital circuit. All of the functional blocks may be implemented as a single circuit, such as an ASIC, SoC, SiP, FPGA, PAL, PLA, FPLA, PLD, or the like. Alternatively, blocks may spread across multiple devices; each block may be implemented on a single device; and/or the digital circuit may be implemented using some other combination of devices. The digital circuit 100 may comprise one or more signal lines 116, 122, 124, 126, 132, 134 configured to convey signals among circuit components. The signal lines 116, 122, 124, 126, 132, 134 may be metal layers, wires, transmission lines, optical fibers, an optical transmission medium, a wave guide, and/or the like.

At a particular time during operation of the digital circuit 100, the power management controller 110 may power down one section of the circuit 100, such as a power-saving block 120, by sending a power-down signal using a power-down signal line 116. Another section of the circuit may remain powered such as an always-powered block 130. In other embodiments, a circuit may have more than one always-powered block and/or more than one power-saving block. The power-saving block 120 may input signal lines 132, 134 from the always-powered block 130 and output signal lines 122, 124, 126 to the always-powered block 130. The input signal lines 132, 134 from the always-powered block 130 may not disrupt the circuit 100 other than to produce minor additional energy consumption. However, the output signal lines 122, 124, 126 from the power-saving block 120 to the always-powered block 130 may significantly disrupt the functioning of the always-powered block 130 and the entire circuit 100.

Digital circuit components, such as logical gates, may be designed to have an output very near the voltage of either the low voltage power supply rail (e.g., a logical low or logical zero) or the high voltage power supply rail (e.g., a logical high or logical one). However, logical gates may also enter a metastable state that is neither logically high nor logically low. Moreover, the metastable state may be propagated to other components if a signal at a metastable level is input into those other components. The metastable state may propagate to sufficient components to render important portions or an entire digital circuit non-functional, and the digital circuit may be unable to recover from this condition.

The power-saving block 120 may cause a metastable state to enter the digital circuit 100 in at least two ways. First, the output signal lines 122, 124, 126 may be neither logically high nor logically low during the power-down process. Although the output signal lines 122, 124, 126 may eventually reach a logical state once sufficient time passes from power being removed, they may remain in an undefined logical state long enough to cause components of the always-powered block 130 to become metastable. The metastable condition may not be corrected when the output signal lines 122, 124, 126 reach a logical state, or the metastable state may have propagated to other elements of the always-powered block 130 in an irreversible manner.

Second, the output signal lines 122, 124, 126 may vary between logical states during the power-down process. Components, such as flip-flops, may have a setup requirement that an input not change within a certain time before a triggering clock edge and a hold requirement that an input not change within a certain time after the triggering clock edge. The setup and/or hold requirements may be violated due to the output signal lines 122, 124, 126 changing during the power-down process. The setup or hold violation may cause a flip-flop in the always-powered block 130 to enter a metastable state. As discussed above, the metastable state may propagate through the circuit before the flip-flop returns to a valid state.

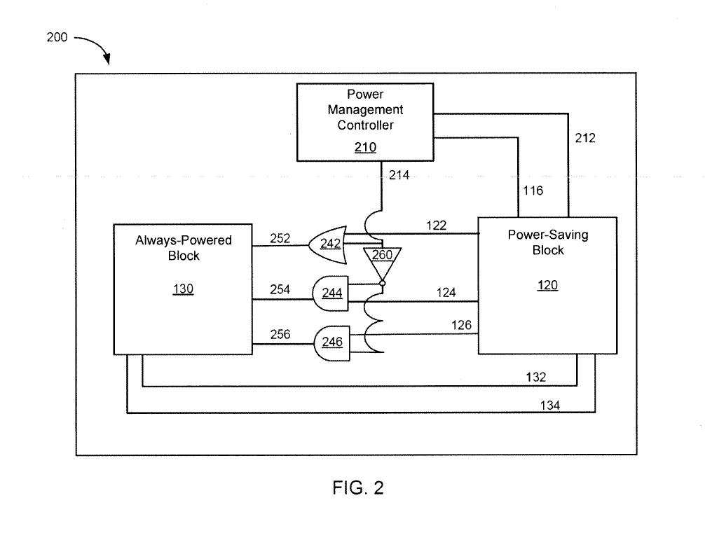

FIG. 2 is a block diagram of a digital circuit 200 with powered isolation gates 242, 244, 246 coupled to the output signal lines 122, 124, 126 from the power-saving block. The powered isolation gates 242, 244, 246 may be placed on the boundary between the always-powered 130 and power-saving blocks 120. The isolation gates 242, 244, 246 may output stable signals to the always-powered block 130 on stable output signal lines 252, 254, 256. The isolation gates 242, 244, 246 may take as inputs an isolation signal line 214 controlled by a power management controller 210 and the output signal lines 122, 124, 126 from the power-saving block 120. The isolation gates 242, 244, 246 may be configured to enter a known state when an isolation signal is asserted and to pass signals on the output signals 122, 124, 126 when the isolation signal is not asserted. In other embodiments, isolation gates (not shown) may be placed on the boundary between two power-saving blocks (not shown), such as when the power-saving blocks can be powered down at different times.

For the sake of simplicity, only three signal lines 122, 124, 126 from the power-saving block 120 and three isolation gates 242, 244, 246 are shown. Modern circuits may have many more than three signal lines that require isolation gates. Thus to simplify the design process, the isolation gates 242, 244, 246 may all be selected to be the same type of gate. However, depending on the logical levels on the output signal lines 122, 124, 126, a change on the isolation signal line 214 may cause a change on the stable output signal lines 252, 254, 256. As a result, the setup and hold requirements of flip-flops in the always-powered block 130 may still be violated and create a metastable state. Alternatively, to avoid setup and hold violations, the isolation gates 242, 244, 246 may be selected according to the logical levels on the output signal lines 122, 124, 126 expected from the power-saving block 120 during the power-down process.

If an output signal line 122 from the power-saving block 120 is high during the power-down process, then an OR gate 242 may be used to isolate the always-powered block 130. If the isolation signal line 214 is configured to be high when the power-saving block 120 is being powered down and low when the power-saving block 120 is active, it may be connected directly to the OR gate 242. When the isolation signal line 214 is low, the stable output signal line 252 from the OR gate 242 may transmit the same logical value as the output signal line 122 from the power-saving block 120. The OR gate 242 may simply pass through the output signal from the power-saving block 120. When the isolation signal line 214 is high, the stable output signal line 252 from the OR gate 242 may be high. The stable output signal line 252 may be clamped high and may not change even if the output signal line 122 from the power-saving block 120 enters a metastable state or becomes low.

A NAND gate may be used as an alternative to the OR gate 242. For a NAND gate, the output signal line 122 from the power-saving block 120 and the isolation signal line 214 may need to pass through inverters before being input into the NAND gate. With the inverted inputs, the NAND gate may have the same properties discussed above for the OR gate 242. In another embodiment, the isolation signal line 214 may be configured to be low when the power-saving block 120 is being powered down and high when the power-saving block 120 is active. Then, to maintain the same functionality, the isolation signal line 214 may need to be inverted before being input to the OR gate 242 and may be either directly input into any NAND gates or passed through a non-inverting buffer before entering any NAND gates.

If output signal lines 124, 126 from the unpowered block are low during the power-down process, then AND gates 244, 246 may be used to isolate the powered block. If the isolation signal line 214 is high when the power-saving block 120 is being powered down and low when the power-saving block 120 is active, it may need to be inverted before being input to the AND gates 244, 246. In the illustrated embodiment, a single inverter 260 may be used for both AND gates 244, 246. In other embodiments, there may be an inverter for every AND gate or there may be some number of inverters in between a single inverter for all AND gates and an inverter for every AND gate. The number of inverters and/or the size of the inverters may be selected to minimize delay. When the isolation signal line 214 is low (and a logical high is input by the AND gates 244, 246), the stable output signal lines 254, 256 from the AND gates 244, 246 may transmit the same logical values as the output signal lines 124, 126 from the power-saving block 120. The AND gates 244, 246 may simply pass through the output signals from the power-saving block 120. When the isolation signal line 214 is high (and a logical low is input by the AND gates 244, 246), the stable output signal lines 254, 256 from the AND gates 244, 246 may be low. The stable output signal lines 254, 256 may be clamped low and may not change even if the output signal lines 124, 126 from the power-saving block 120 enter a metastable state or become high.

NOR gates may also be used as alternatives to the AND gates 244, 246. For NOR gates, the output signal lines 124, 126 from the power-saving block 120 may need to pass through inverters before being input into the NOR gates, and the isolation signal line 214 may be directly input to the NOR gates or passed through a non-inverting buffer. With these inputs, the NOR gates may have the same properties discussed above for the AND gates 244, 246. In another embodiment, the isolation signal line 214 may be configured to be low when the power-saving block 120 is being powered down and high when the power-saving block 120 is active. Then, to maintain the same functionality, the isolation signal line 214 may be either directly fed into the AND gates 244, 246 or passed through a non-inverting buffer before entering the AND gates 244, 246 and may need to be inverted before being input to any NOR gates.

Because the OR gate 242 may only clamp signals high and the AND gates 244, 246 may only clamp signals low, the output signal lines 122, 124, 126 may need to be at a known logical level before the gates are selected. A circuit designer may be required to know at the design stage what the logical values on the output signal lines 122, 124, 126 will be during dynamic operation. Usually during dynamic operation, the logical values on the output signal lines 122, 124, 126 will be changing and cannot be definitively determined. To prevent the logical values on the output signal lines 122, 124, 126 from dynamically changing during the power-down process, the power management controller 210 may carefully control a reset signal line 212, the isolation signal line 214, and the power-down signal line 116 to ensure that the output signal lines 122, 124, 126 will be at a known logical level when the isolation signal is asserted.

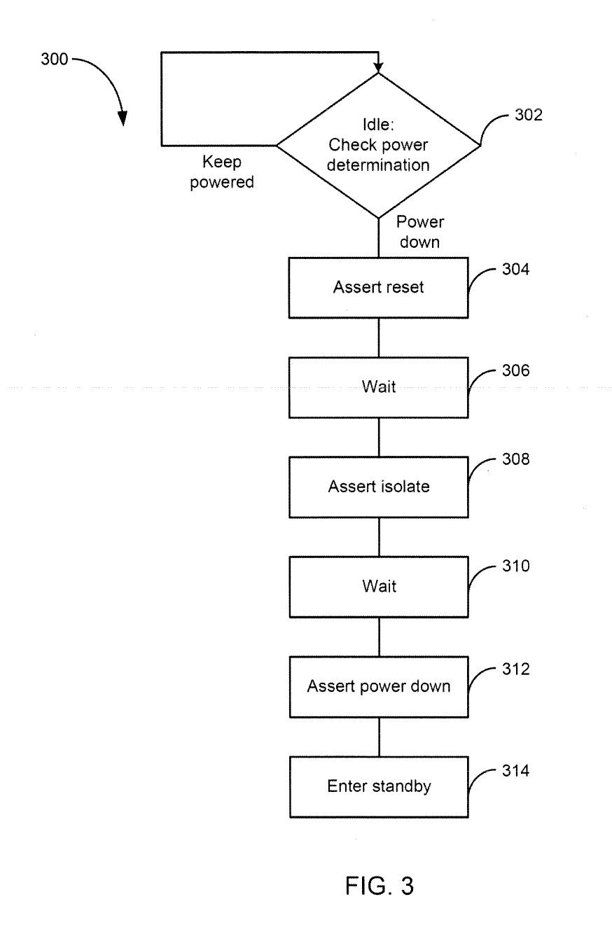

FIG. 3 is a flow diagram of a method 300 for powering down the power-saving block 120 while ensuring the output signals 122, 124, 126 are at a determinable logic level when the isolation signal 214 is asserted. The method 300 may be implemented by the power management controller block 210 of the digital circuit 200. For example, the power management controller block 210 may comprise a state machine configured to perform the method 300. Alternatively, the method 300 may be implemented by multiple blocks or by a separate circuit on another chip.

The power management controller 210 may start 302 in an idle state. During this state, power may continue to flow to the power-saving block 120. The power management controller 210 may check to see whether the power-saving block 120 should be powered down. If the power-saving block 120 should not be powered down, the power management controller 210 may remain in the idle state. Otherwise, it may proceed to step 304. The power management controller 210 may itself determine whether the power-saving block 120 should be powered down, or another block in the digital circuit 200 may inform the power management controller 210 that the power-saving block 120 is no longer in use and may be powered down.

Once the power management controller 210 determines that the power-down sequence should begin, it may assert 304 the reset signal to the power-saving block 120. In some embodiments, the reset signal may be defined to be asserted when it is logically high. In others, the reset signal may be defined to be asserted when logically low. The reset signal may cause flip-flops, registers, counters, and other state devices to enter a pre-determined state. The state may not need to be known to the power management controller 210 or even a circuit designer, as long as the state devices enter the same state whenever the reset signal is asserted. If the state devices always enter the same state, the output signal lines 122, 124, 126 from the power-saving block 120 may be at the same logical value any time the reset signal is asserted.

The power management controller 210 may wait 306 a first predetermined period of time to ensure the reset signal has time to propagate and the output signal lines 122, 124, 126 have settled. In some embodiments, the power management controller 210 may wait for one triggering clock edge of the lowest frequency clock in the power-saving block 120. In other embodiments, the power management controller 210 may be configured to act more conservatively and wait two or even many clock cycles of the lowest frequency clock in the power-saving block 120 before proceeding.

The power management controller 210 may assert 308 the isolation signal. As discussed above, the assertion of the isolation signal may result in the isolation gates 242, 244, 246 clamping the stable output signal lines 252, 254, 256 received by the always-powered block 130. Because the output signal lines 122, 124, 126 from the power-saving block 120 have settled, the isolation gates 242, 244, 246 may be configured to not change their output in response to the isolation signal being asserted.

The power management controller 210 may wait 310 a second predetermined period of time for the isolation signal to propagate. In some embodiments, the isolation signal may be propagated asynchronously. However, in other embodiments, it may be desirable to pass the isolation signal through a state device so that it propagates synchronously. If the isolation signal propagates asynchronously, the power management controller 210 may only wait until the triggering edge of the next clock cycle for the clock driving the power management controller 210. In other embodiments, the wait may be computed using other clocks on the circuit, or the wait time may be more conservative such as two or many clock cycles. If the isolation signal propagates synchronously, the wait may be computed based on the expected propagation time. The wait may also be computed more conservatively and include extra clock cycles.

After the power management controller 210 has waited sufficient time, it may assert 312 the power-down signal. The power-down signal line 116 may be one of the voltage rails, in which case, the power-down signal may be asserted by directly reducing the voltage between the power-saving block's 120 power rails to zero. In other embodiments, the power-down signal may signal to a different block or to the power-saving block 120 itself that power should be removed from the power-saving block 120. The different block or the power-saving block 120 may then ensure that there is no voltage across the power rails of the power-saving block 120. Because all the stable output signal lines 252, 254, 256 from the isolation gates 242, 244, 246 have been clamped, asserting 312 the power-down signal may not affect any other parts of the digital circuit.

The power management controller 210 may finish by entering 314 standby mode. In standby mode, the power management controller 210 may continue to assert the reset signal, isolation signal, and power-down signal. The power management controller 210 may remain in standby mode until the power-saving block 120 needs to be powered up again.

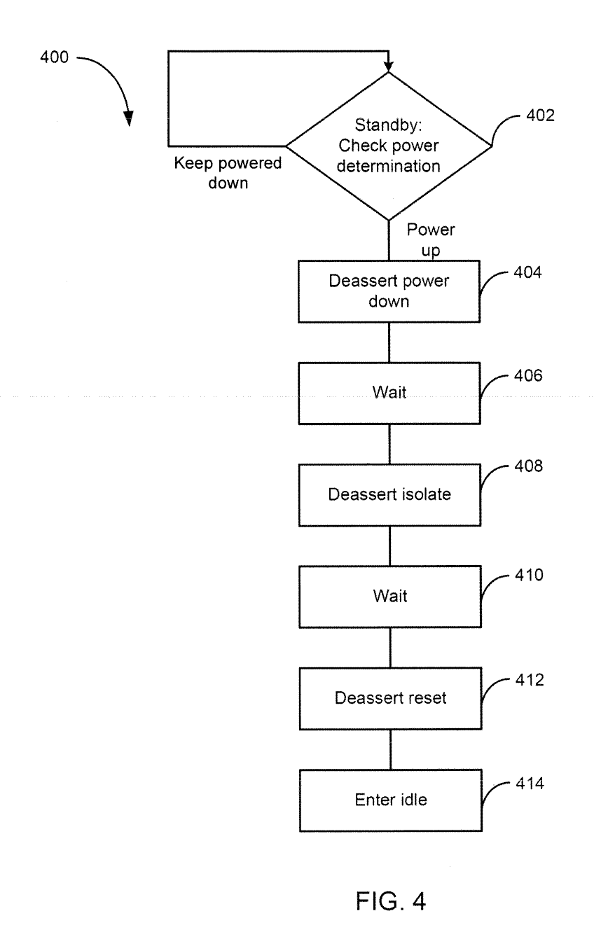

FIG. 4 is a flow diagram of a method 400 for powering up a power-saving block 120 while ensuring that the always-powered block 130 does not enter a metastable state. As discussed above, the always-powered block 130 may enter a metastable state if a signal between high and low is output by the power-saving block 120 during power up. Alternatively, a changing signal from the power-saving block 120 may violate the setup or hold requirements of a flip-flop or other state device in the always-powered block 130. The setup and/or hold violation could then cause the flip-flop to enter a metastable state that is propagated to other elements of the always-powered block 130.

The power management controller 210 may begin 402 in standby mode with the reset signal, isolation signal, and the power-down signal asserted. The power management controller 210 may check to see whether the power-saving block 120 should be powered up. If the unpowered block should remain powered down, the power management controller 210 may stay in the standby state. Otherwise, it may proceed to step 404. Like when determining whether to power down, the power management controller 210 may itself determine whether a block needs to be powered up, or another block in the digital circuit 200 may inform the power management controller 210 that the power-saving block 120 needs to be used and should be powered up.

To power up the power-saving block 120, the power management controller 210 may deassert 404 the power-down signal. As a result, power may be provided to the power-saving block 120. The power management controller 210 may deassert the power-down signal by directly increasing the voltage between the power rails to the power-saving block 120. In other embodiments, the deasserted power-down signal may signal to a different block or the power-saving block 120 itself that power should be restored to the power-saving block 120. The different block or power-saving block 120 may respond by increasing the voltage across the power rails to the power-saving block 120.

The power management controller 210 may need to wait 406 a third predetermined period of time for the power-saving block 120 to power up. Many of the components of the power-saving block 120 may have capacitance associated with them. When power is restored to the power-saving block 120, the capacitance of the components may need to be charged for the outputs 122, 124, 126 from the power-saving block 120 to reach a definite logical level. Before the power-saving block 120 is completely charged, the output signal lines 122, 124, 126 may be at a level that would induce a metastable state in the always-powered block 130. The more components the power-saving block 120 has, the longer it may take for the output signal lines 122, 124, 126 to reach a stable state. Accordingly, the power management controller 210 may wait long enough for the output signal lines 122, 124, 126 to reach a stable level. In some embodiments, the wait time may be based on the expected time for the power-saving block 120 to stabilize. In other embodiments, the power management controller 210 may be configured to be reusable in various circuits and may wait the time expected for most blocks to have stabilized. In still other embodiments, the power management controller 210 may be configured to be more conservative and may wait longer or may wait a length of time selected according to other criteria.

Once the output signal lines 122, 124, 126 have stabilized, the power management controller 210 may deassert 408 the isolation signal. Afterwards, the isolation gates 242, 244, 246 may pass logical values from the output signal lines 122, 124, 126 from the power-saving block 120 to the always-powered block 130. Because the reset signal is still asserted, the output signal lines 252, 254, 256 from the isolation gates 242, 244, 246 may remain at a stable logical value in response to the isolation signal being deasserted.

After deasserting the isolation signal, the power management controller 210 may wait 410 a fourth predetermined period of time for the deassertion of the isolation signal to propagate. In some embodiments, the isolation signal may propagate in approximately the same amount of time whether it is being asserted or deasserted. The power management controller 210 may then wait the same number of clock cycles in step 410 as it did in step 310. In other embodiments, the power management controller 210 may act more or less conservatively during power up than during the power-down process or vice versa.

The power management controller 210 may deassert 412 the reset signal once the isolation signal has propagated. Once the reset signal has been deasserted, the power-saving block 120 may resume normal function. In some embodiments, the power-saving block 120 may have multiple reset signal lines or multiple blocks may be powered up at the same time. In those embodiments, the power management controller 210 may need to deassert reset signals in a particular order and/or wait between each reset deassertion.

The power management controller 210 may return 414 to the idle state once it has completed deasserting the reset signal. The power management controller 210 may continue to deassert the reset signal, isolation signal, and power-down signal while in the idle state. As discussed with step 302, the power management controller 210 may remain in the idle state until the power-saving block 120 needs to be powered down again.

Although the power-down and power-up methods 300, 400 can be used to ensure that the output signal lines 122, 124, 126 will be a definite level, they may provide no guarantee of what that level will be. One way of ensuring that the output signal lines 122, 124, 126 are known may be to build the power-saving block 120 according to design rules that ensure the output signal lines 122, 124, 126 are at an expected logical value when the reset signal is asserted. For example, all output signals lines 122, 124, 126 could be required to be zero when the reset signal has been asserted. If all output signal lines 122, 124, 126 are required to be the same value when the reset signal is asserted, then the same type of gate may be used for every isolation gate 242, 244, 246. In the case where the output signal lines 122, 124, 126 are required to be zero, AND gates (or NOR gates) may be used for every isolation gate.

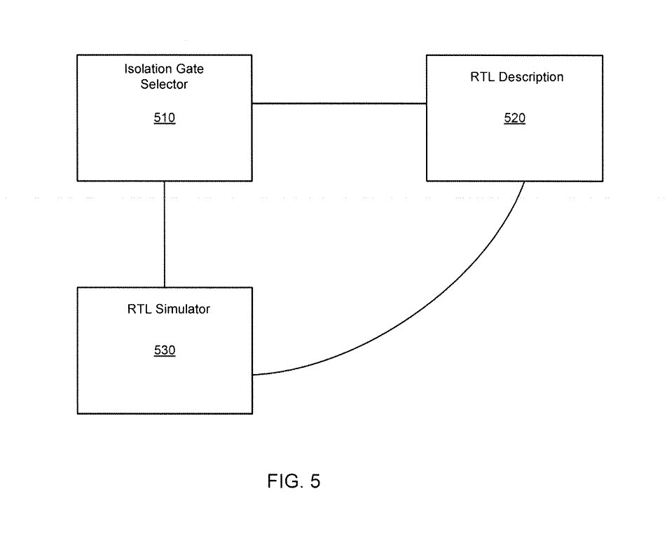

Design rules may be helpful when making a new circuit block, but older circuit blocks or circuit blocks designed by a third party may not have been designed in accordance with these design rules. For these noncompliant circuit blocks, a different method of selecting gates may need to be used. FIG. 5 is a block diagram of a system 500 for selecting appropriate isolation gates to add to a circuit containing a noncompliant power-saving block. The system 500 may comprise an isolation gate selector 510, a register transfer level (RTL) description of the circuit or circuit block 520, and an RTL simulator 530. In other embodiments, a transistor level description, a gate level description or a behavioral or algorithmic description of the circuit or circuit block and appropriate simulator may be used. Some simulators may be capable of providing multiple kinds of simulation, such as transistor level simulation, gate level simulation, RTL simulation, and behavioral simulation. In still other embodiments, the circuit or circuit block may be a digital circuit implemented on an ASIC, SoC, SiP, FPGA, PAL, PLA, FPLA, PLD, or the like or more than one such device. The simulator may then comprise a hardware and/or software controller for the circuit or circuit block. For digital circuits comprising a noncompliant circuit block, the outputs of the noncompliant circuit block may need to be readable by the simulator.

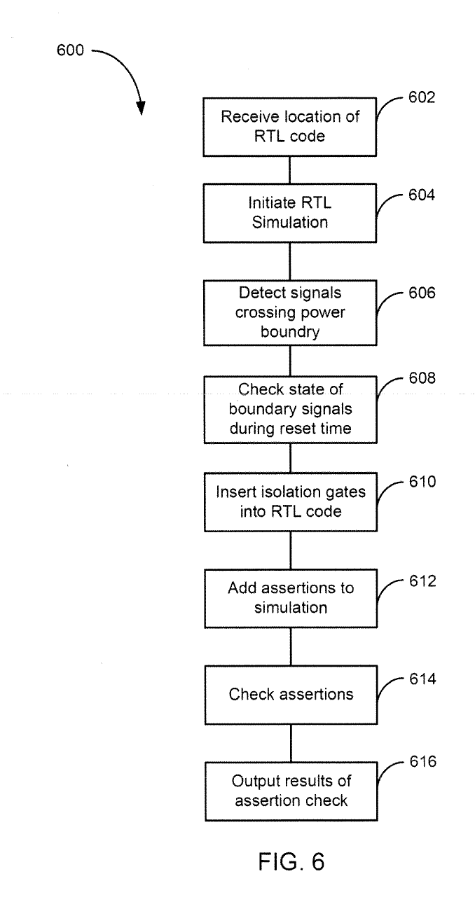

FIG. 6 is a flow diagram of a method 600 that may be used by the isolation gate selector 510 to determine the appropriate isolation gates for a noncompliant circuit block, insert those isolation gates into the RTL description 520, and test to ensure the proper isolation gates were selected. The isolation gate selector 510 may begin by receiving 602 the location of the RTL description 520 from a user. In other embodiments, another software program may request that the isolation gate selector 510 operate on a particular RTL description. For example, a script may repeatedly call the isolation gate selector 510 to operate on a series of descriptions.

The isolation gate selector 510 may call 604 the simulator 530 to simulate the operation of the circuit or circuit block described by the RTL description 520. The isolation gate selector 510 may provide the simulator with instructions on what inputs to simulate. The inputs may be selected to ensure that the reset signal to the noncompliant circuit block is asserted in the simulation and that sufficient time is simulated after the assertion for the outputs from the noncompliant circuit block to settle. The simulator 530 may access the RTL description 520 directly to perform the simulation. In other embodiments, the isolation gate selector 510 may act as a broker that provides the RTL description 520 to the simulator 530.

Next, the isolation gate selector 510 may detect 606 what signals are being output from blocks designed to be powered down to blocks that are always powered or may be powered down at different times. In some embodiments, the isolation gate selector 510 may take as an input a list of circuit blocks that form a boundary with another power domain and indications of whether each circuit block would be powered up or powered down. The isolation gate selector 510 may search for input lines to the powered up circuit blocks from other domains and output lines from the powered down circuit blocks to other domains. In some embodiments, the isolation gate selector 510 may not identify a signal line that has already been identified. In other embodiments, the isolation gate selector 510 may determine which circuit blocks are on different power domains by examining which power lines feed each circuit block. It may find which signal lines are crossing boundaries between differently powered blocks. When only the noncompliant circuit block is being simulated, the isolation gate selector 510 may simply detect what signal lines are output from the noncompliant circuit block. Step 606 may be performed prior to or concurrently with the simulation 604 of the circuit in some embodiments.

Once the circuit has been simulated 604 and the output signal lines have been identified 606, the isolation gate selector 510 may determine 608 the logical level of the signals output by the noncompliant circuit block. The isolation gate selector 510 may examine the output from the simulator 530 to determine the logical levels of the output signals after a predetermined amount of time within the simulation has passed. The predetermined simulation time may be selected to be sufficient for the output signals to stabilize. Because the isolation gate selector 510 provided the inputs to the simulation, it may be able to determine when the reset signal to the noncompliant block was asserted and may check the logical levels of the output signals an appropriate amount of time afterwards. In other embodiments, the isolation gate selector 510 may check the simulation results to see when the reset signal to the noncompliant circuit block was asserted, make sure the reset signal remained asserted, and check the logical levels of the output signals an appropriate amount of time afterwards.

The isolation gate selector 510 may insert 610 appropriate isolation gates at appropriate locations in the RTL description 520 to create a modified RTL description. As discussed previously, the appropriate isolation gates may be determined by the level of the output signal while the reset signal was asserted. In some embodiments, the isolation gate selector 510 may always use AND gates and OR gates. In other embodiments, the isolation gate selector 510 may always use other types of gates, or the isolation gate selector 510 may allow the user to select the type of gates with a default when no type is selected. The isolation gate selector 510 may locate the output signal lines from the noncompliant circuit block in the RTL description 520 and may edit the RTL 520 description to add the isolation gate and any inverters necessary to ensure proper functionality of the isolation gate. The isolation gate selector 510 may create an inverter for the isolation signal at every gate that requires the isolation signal be inverted, or it may create a global inverted isolation signal that it inputs into every gate that requires the isolation signal be inverted. In some embodiments, the isolation gate selector 510 may choose a single inverter for a small number of gates it determines are likely to be near one another. For those embodiments where one or more programmable devices are used instead of the RTL description 520, the isolation gate selector 510 may reprogram the programmable device with the appropriate gates inserted into the circuit.

In some embodiments, the isolation gate selector 510 may add 612 assertions to the simulation. The isolation gate selector 510 may begin by inserting the assertions into the modified RTL description. In some embodiments, these assertions may check that the output from each isolation gate does not change when the isolation signal is asserted. In other embodiments, the assertions may check that the output signal from the isolation gates is the appropriate level for that isolation gate a sufficient time after the reset signal has been asserted but before the isolation signal is asserted. Alternatively, or in addition, any equivalent assertions may be inserted that ensure the output signals from the isolation gates behave correctly during the power-down method 300.

The isolation gate selector 510 may check 614 the outputs from the assertions. To begin, the isolation gate selector 510 may call the simulator 530 to simulate the operation of the circuit with assertion checking during simulation. In some embodiments, the isolation gate selector 510 may convert the modified RTL description into a gate level description of the circuit first. The simulator 530 may simulate the circuit based on the gate level description with assertion checking. In other embodiments, the modified RTL description may not be converted, may be converted to a different description, and/or may be programmed on to a programmable digital circuit implementing device. An appropriate simulator may then be used based on whether the modified RTL description has been converted or not.

After the simulator 530 has simulated the modified circuit, the isolation gate selector 510 may determine if any problems were detected. The isolation gate selector 510 may examine the output from the simulator 530 including the results of all assertion checking that was done during the simulation. If the assertions do not indicate any problems, then the isolation gate selector 510 may decide that the correct isolation gates have been inserted into the circuit. In some embodiments, when there are errors, the isolation gate selector 510 may return to step 610 and changes the type of the isolation gate generating the error. The isolation gate selector 510 may only attempt once to fix the isolation gate or may attempt more than once. Alternatively, or in addition, the isolation gate selector 510 may generate a list of output signal lines where the isolation gate selector 510 was unable to find a suitable isolation gate.

The isolation gate selector 510 may output 616 the results of the assertion checking to the user. Outputting may be done by displaying a message on a monitor indicating that the method 600 has completed successfully and/or that some gates were not selected successfully. Alternatively, the isolation gate selector 510 may only produce a message if the method 600 did not complete successfully. The user may assume successful completion if no message is produced. In some embodiments, the list of output signal lines without proper isolation gates may be inserted into a file. The isolation gate selector 510 may display an indication of the file location on the monitor and/or the user may know the file location from a manual or the like. In other embodiments, the list of output signal lines may be displayed directly on the monitor. If another software program called the isolation gate selector 510, the isolation gate selector 510 may return a code to the software program indicating whether the program completed successfully.

It will be understood by those having skill in the art that many changes may be made to the details of the above-described embodiments without departing from the underlying principles of the disclosure. The scope of the present disclosure should, therefore, be determined only by the following claims.

1. A method of isolating a power-saving digital circuit block of a digital circuit from a remainder of the digital circuit, the method comprising:
asserting a reset signal to the power-saving digital circuit block, wherein the power-saving digital circuit block comprises a plurality of output signal lines coupled to the remainder of the digital circuit;
asserting an isolation signal to a plurality of isolation gates, wherein each of the plurality of isolation gates is electrically coupled with a corresponding one of the plurality of output signal lines, wherein each isolation gate is electrically coupled with the isolation signal, and wherein each isolation gate enters a known state when the isolation signal is asserted; and
asserting a power-down signal to the power-saving digital circuit block.

2. The method of claim 1, further comprising waiting a predetermined period of time after asserting the reset signal and before asserting the isolation signal.

3. The method of claim 2, wherein the predetermined period of time comprises one clock cycle of a slowest clock of the power-saving digital circuit block.

4. The method of claim 1, further comprising waiting a predetermined period of time after asserting the isolation signal and before asserting the power-down signal.

5. The method of claim 4, wherein the predetermined period of time comprises one clock cycle of a clock of the digital circuit.

6. The method of claim 1, further comprising:
entering a standby state;
determining whether to power up the power-saving digital circuit block;
deasserting the power-down signal;
deasserting the isolation signal; and
deasserting reset signal.

7. The method of claim 6, further comprising waiting a predetermined period of time after deasserting the power-down signal and before deasserting the isolation signal.

8. The method of claim 7, wherein the predetermined period of time allows capacitances of all components of the power-saving digital circuit block to charge.

9. The method of claim 6, further comprising waiting a predetermined period of time after deasserting the isolation signal and before deasserting the reset signal.

10. The method of claim 9, wherein the period of time comprises one clock cycle of a clock of the digital circuit.

11. A power management digital circuit for isolating a power-saving digital circuit block of a digital circuit from a remainder of the digital circuit, the power management digital circuit comprising:
a reset signal line;
an isolation signal line;
a power-down signal line; and
a state machine configured to perform a method of powering down the power-saving digital circuit block, the method comprising:
determining whether to power down the power-saving digital circuit block;
asserting a reset signal on the reset signal line;
asserting an isolation signal on the isolation signal line; and
asserting a power-down signal on the power-down signal line.

12. The power management digital circuit of claim 11, wherein the method of powering down the power-saving digital circuit block further comprises waiting a predetermined period of time after asserting the reset signal and before asserting the isolation signal.

13. The power management digital circuit of claim 12, wherein the power-saving digital circuit block comprises a slowest clock, and wherein the predetermined period of time comprises one clock cycle of the slowest clock.

14. The power management digital circuit of claim 11, wherein the method of powering down the power-saving digital circuit block further comprises waiting a predetermined period of time after asserting the isolation signal and before asserting the power-down signal.

15. The power management digital circuit of claim 14, further comprising a clock, wherein the predetermined period of time comprises one cycle of the clock.

16. The power management digital circuit of claim 11, wherein the state machine is configured to perform a method of powering up the power-saving digital circuit block, the method comprising:
determining whether to power up the power-saving digital circuit block;
deasserting the power-down signal;
deasserting the isolation signal; and
deasserting reset signal.

17. The power management digital circuit of claim 16, wherein the method of powering up the power-saving digital circuit block further comprises waiting a predetermined period of time after deasserting the power-down signal and before deasserting the isolation signal.

18. The power management digital circuit of claim 17, wherein the predetermined period of time allows capacitances of all components of the power-saving digital circuit block to charge.

19. The power management digital circuit of claim 16, wherein the method of powering down the power-saving digital circuit block further comprises waiting a predetermined period of time after deasserting the isolation signal and before deasserting the reset signal.

20. The power management digital circuit of claim 19, further comprising a clock, wherein the predetermined period of time comprises one cycle of the clock.

21. A computer-implemented method of isolating a power-saving digital circuit block of an initial digital circuit from a remainder of the initial digital circuit, the method comprising:
simulating, using a processor, an initial description of the initial digital circuit including the power-saving digital circuit block, wherein a reset signal is asserted during simulation;
identifying, using the processor, a plurality of output signal lines output by the power-saving digital circuit block;
determining, using the processor, a plurality of output levels corresponding to each of the plurality of output signal lines a predetermined simulation time after the reset signal has been asserted; and.
inserting a plurality of isolation gates into the initial description of the initial digital circuit to create a modified description of a modified digital circuit, wherein the plurality of isolation gates are determined from the plurality of output levels.

22. The computer-implemented method of claim 21, further comprising:
inserting a plurality of assertions into the modified description of the modified digital circuit to create an assertion-checking description of the modified digital circuit, wherein each of the plurality of assertions corresponds to each of the plurality of output signals;
simulating the assertion checking description; and
checking assertion outputs from the plurality of assertions to determine if each of the plurality of isolation gates is correct.

23. The computer-implemented method of claim 21, wherein the initial description of the initial digital circuit is a register transfer level description and the modified description of the modified digital circuit is a gate level description.

24. The computer system implemented method of claim 21, wherein AND isolation gates are selected for logically low output levels and OR isolation gates are selected for logically high levels.

25. The computer system implemented method of claim 21, wherein each of the plurality of isolation gates is coupled with a corresponding one of the plurality of output signal lines, and wherein each of the plurality of isolation gates is coupled with an isolation signal.

26. A non-transitory computer-readable storage medium including computer-readable instruction code for performing a method of isolating a power-saving digital circuit block of an initial digital circuit from a remainder of the initial digital circuit, the method comprising:
simulating an initial description of the initial digital circuit, wherein a reset signal is asserted during simulation;
identifying a plurality of output signal lines output by the power-saving digital circuit block;
determining a plurality of output levels corresponding to each of the plurality of output signal lines a predetermined simulation time after the reset signal has been asserted; and
inserting a plurality of isolation gates into the initial description of the initial digital circuit to create a modified description of a modified digital circuit, wherein the plurality of isolation gates are determined from the plurality of output levels.
